(19) United States
(12) Patent Application Publication
(10) Pub. No.: US 2014/0240079 A1
(43) Pub. Date: Aug. 28, 2014

(54) METHOD FOR MANUFACTURING THIN METAL WIRE ELECTROMAGNETIC SHIELD, THIN METAL WIRE ELECTROMAGNETIC SHIELD, AND STATIONARY INDUCTION APPARATUS INCLUDING THE SAME

(71) Applicants: Kenichi Mino, Chiyoda-ku (JP); Ryuichi Nishiura, Chiyoda-ku (JP)

(72) Inventors: Kenichi Mino, Chiyoda-ku (JP); Ryuichi Nishiura, Chiyoda-ku (JP)

(73) Assignee: MITSUBISHI ELECTRIC CORPORATION, Chiyoda-ku ,Tokyo (JP)

(21) Appl. No.: 14/352,775

(22) PCT Filed: Nov. 22, 2011
(86) PCT No.: PCT/JP2011/076858

§ 371 Date: Apr. 18, 2014

(51) Int. Cl. H05K 9/00; H01F 27/36

(52) U.S. Cl. CPC H05K 9/0081; H01F 27/367
USPC 336/84 C; 174/350; 156/180

(57) ABSTRACT

A method for manufacturing a thin metal wire electromagnetic shield includes the steps of preparing a thin metal wire bundle unified by bundling a plurality of thin metal wires each having a surface coated with an insulating material, and compression-molding the thin metal wire bundle by press working.

### TECHNICAL FIELD

The present invention relates to a method for manufacturing a thin metal wire electromagnetic shield, a thin metal wire electromagnetic shield, and a stationary induction apparatus including the same.

### BACKGROUND ART

A transformer, which is a main apparatus in a power station or a substation, is required to have a reduced internal heat generation, as it handles a higher voltage, has a higher capacity, and has a smaller size for reducing manufacturing cost, in recent years.

One of the factors of internal heat generation in the transformer is heat generation due to an eddy current generated by a leaked magnetic flux from a coil entering a metal structural material. As a countermeasure therefor, an electromagnetic shield shielding the leaked magnetic flux from the coil is arranged inside the transformer.

Japanese Patent Laying-Open No. 58-181612 (PTD 1) is a prior art document disclosing a method for manufacturing a plastic molded article having electromagnetic shielding properties. In the method for manufacturing a plastic molded article having electromagnetic shielding properties described in PTD 1, a fluid plastic material is injected into a cavity of a mold filled with a conductive material to integrally solidify the conductive material and the plastic material.

### CITATION LIST

### Patent Document

PTD 1: Japanese Patent Laying-Open No. 58-181612

### SUMMARY OF INVENTION

### Technical Problem

In order to improve the magnetic flux shielding capability of an electromagnetic shield, it is necessary to increase the space factor of the conductive material. When the plastic material and the conductive material are unified, it is not possible to increase the space factor of the conductive material, because the plastic material has a high space factor.

The present invention has been made to solve the aforementioned problem, and one object of the present invention is to provide a method for manufacturing a thin metal wire electromagnetic shield, a thin metal wire electromagnetic shield, and a stationary induction apparatus including the same, capable of increasing the space factor of a conductive material and improving the magnetic flux shielding capability of an electromagnetic shield.

### Solution to Problem

A method for manufacturing a thin metal wire electromagnetic shield in accordance with the present invention includes the steps of preparing a thin metal wire bundle unified by bundling a plurality of thin metal wires each having a surface coated with an insulating material, and compression-molding the thin metal wire bundle by press working.

### Advantageous Effects of Invention

According to the present invention, the space factor of a conductive material can be increased and the magnetic flux shielding capability of an electromagnetic shield can be improved.

### BRIEF DESCRIPTION OF DRAWINGS

FIG. 1 is a flowchart illustrating a method for manufacturing a thin metal wire electromagnetic shield in accordance with. Embodiment 1 of the present invention.

FIG. 2 is a perspective view showing a plurality of thin metal wires in a stacked state.

FIG. 3 is a partial perspective view showing a configuration of a unified thin metal wire bundle in the same embodiment.

FIG. 4 is a side view showing a configuration of a press working machine for pressing the thin metal wire bundle.

FIG. 5 is a partial perspective view showing an outer appearance of the thin metal wire electromagnetic shield formed by being compression-molded by press working in the same embodiment.

FIG. 6 is a partial perspective view showing a configuration of a unified thin metal wire bundle in Embodiment 2 of the present invention.

FIG. 7 is a partial perspective view showing an outer appearance of a thin metal wire electromagnetic shield formed by being compression-molded by press working in the same embodiment.

FIG. 8 is a partial cross sectional view showing a configuration of a shell-type transformer in accordance with Embodiment 3 of the present invention.

FIG. 9 is a partial cross sectional view showing a configuration of a core-type transformer in accordance with Embodiment 4 of the present invention.

### DESCRIPTION OF EMBODIMENTS

Hereinafter, a method for manufacturing a thin metal wire electromagnetic shield, and a thin metal wire electromagnetic shield in accordance with Embodiment 1 of the present invention will be described with reference to the drawings. In the following description of the embodiments, identical or corresponding parts in the drawings will be designated by the same reference numerals, and the description thereof will not be repeated.

### Embodiment 1

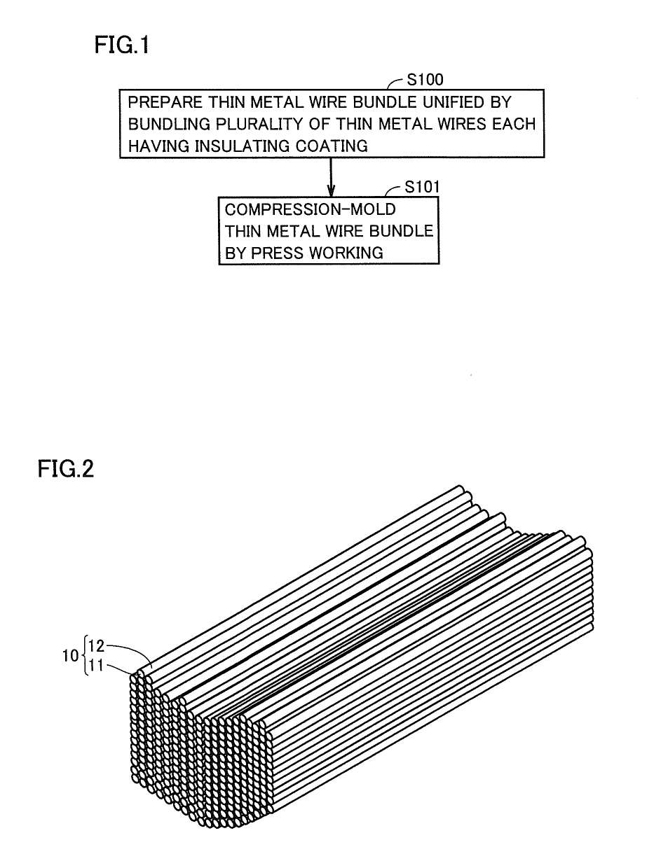

FIG. 1 is a flowchart illustrating a method for manufacturing a thin metal wire electromagnetic shield in accordance with Embodiment 1 of the present invention. As shown in FIG. 1, the method for manufacturing the thin metal wire electromagnetic shield in accordance with Embodiment 1 of the present invention includes the steps of preparing a thin metal wire bundle unified by bundling a plurality of thin metal wires each having a surface coated with an insulating material (S100), and compression-molding the thin metal wire bundle by press working (S101). Hereinafter, each step will be described.

FIG. 2 is a perspective view showing the plurality of thin metal wires in a stacked state. As shown in FIG. 2, each of a plurality of thin metal wires 10 is composed of a conductive material 11 made of, for example, soft iron, and an insulating material 12 coating the surface of conductive material 11.

As insulating material 12, any material can be used as long as it can block an eddy current having an electromotive force of about several volts generated by a magnetic flux entering conductive material 11. For example, an insulating paint containing epoxy resin, or the like can be used as insulating material 12. Preferably, insulating material 12 is made of a hard material and applied thinnly to allow a thin metal wire bundle 20 to be closely compressed when it is compression-molded as described later.

For example, thin metal wire 10 has a diameter of more than or equal to 0.8 mm and less than or equal to 1 mm, and a length of about 3 m. For example, more than or equal to 300 and less than or equal to 500 thin metal wires 10 are used to constitute one thin metal wire electromagnetic shield.

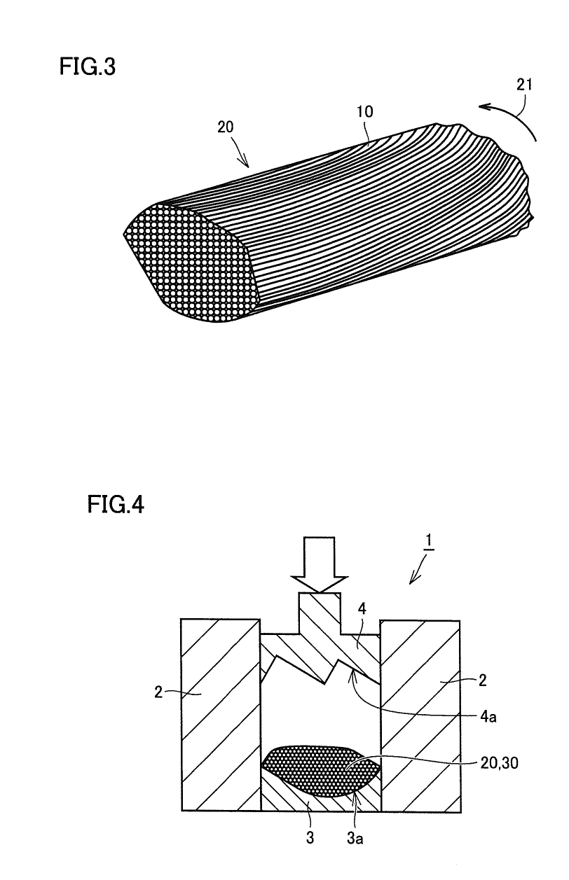

FIG. 3 is a partial perspective view showing a configuration of the unified thin metal wire bundle in the present embodiment. As shown in FIG. 3, in the present embodiment, the thin metal wire bundle is unified by twisting the plurality of thin metal wires 10 in a bundled state. For example, the plurality of thin metal wires 10 are twisted once for each length of 1 m. In order to twist the plurality of thin metal wires 10, both ends thereof may be twisted in directions opposite to each other, or one end thereof on a side closer to the viewer in FIG. 3 may be fixed and the other end thereof may be twisted in a direction indicated by an arrow 21.

The plurality of thin metal wires 10 are twisted in a bundled state, and thereby unified into thin metal wire bundle 20. By compression-molding thin metal wire bundle 20 by press working, a thin metal wire electromagnetic shield 20a having a desired shape is fabricated.

FIG. 4 is a side view showing a configuration of a press working machine for pressing the thin metal wire bundle. As shown in FIG. 4, a press working machine 1 includes a base 2 holding molds, a lower mold 3 fixed to base 2, and an upper mold 4 held by base 2 to be movable in an up-down direction.

On an upper surface of lower mold 3, a lower molding surface 3a which is to come into contact with a portion of a peripheral side surface of thin metal wire bundle 20 is formed. On a lower surface of upper mold 4, an upper molding surface 4a which is to come into contact with the remaining portion of the peripheral side surface of thin metal wire bundle 20 is formed. Lower molding surface 3a and upper molding surface 4a are formed corresponding to the desired shape of thin metal wire electromagnetic shield 20a.

Press working is performed by placing thin metal wire bundle 20 on lower mold 3, moving upper mold 4 downward, and sandwiching thin metal wire bundle 20 between lower molding surface 3a and upper molding surface 4a.

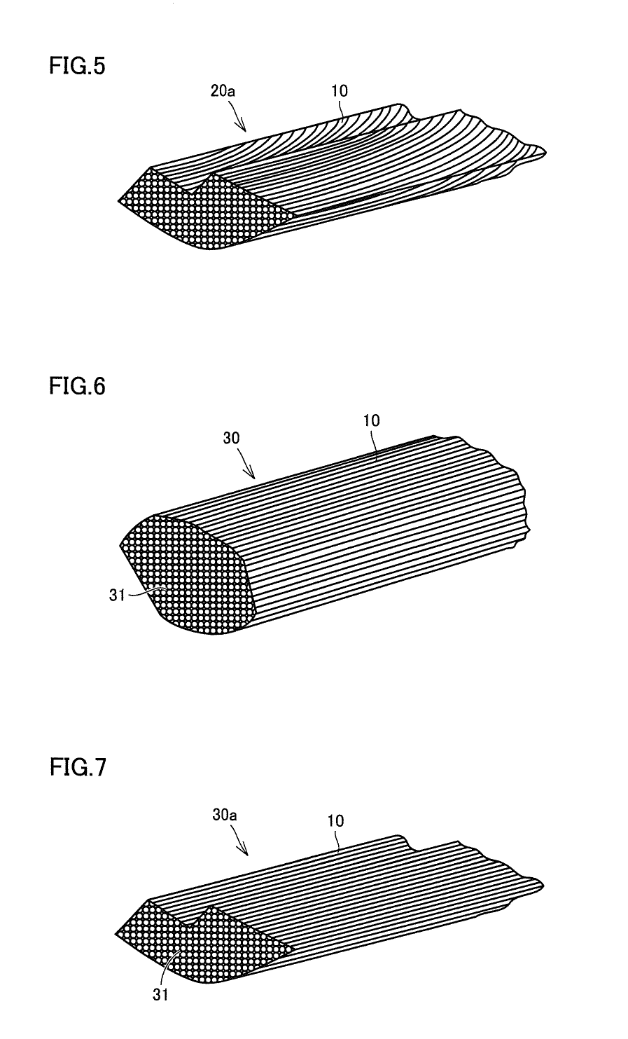

FIG. 5 is a partial perspective view showing an outer appearance of the thin metal wire electromagnetic shield formed by being compression-molded by press working in the present embodiment. As shown in FIG. 5, thin metal wire electromagnetic shield 20a compression-molded by press working has an outer shape which follows the shapes of lower molding surface 3a and upper molding surface 4a.

Since thin metal wire electromagnetic shield 20a is compression-molded, gaps between thin metal wires 10 are reduced. As a result, the space factor of conductive material 11 in thin metal wire electromagnetic shield 20a is higher than the space factor of conductive material 11 in thin metal wire bundle 20.

By forming thin metal wire electromagnetic shield 20a as described above, the space factor of conductive material 11 can be increased and the magnetic flux shielding capability of thin metal wire electromagnetic shield 20a can be improved.

Hereinafter, a method for manufacturing a thin metal wire electromagnetic shield, and a thin metal wire electromagnetic shield in accordance with Embodiment 2 of the present invention will be described. Since the method for manufacturing the thin metal wire electromagnetic shield in accordance with the present embodiment is different from the method for manufacturing the thin metal wire electromagnetic shield in accordance with Embodiment 1 only in a method for unifying a thin metal wire bundle, a description of other features will not be repeated.

### Embodiment 2

FIG. 6 is a partial perspective view showing a configuration of a unified thin metal wire bundle in Embodiment 2 of the present invention. As shown in FIG. 6, in the present embodiment, the thin metal wire bundle is unified by bonding the plurality of thin metal wires 10 together with an adhesive. The plurality of thin metal wires 10 are bonded together with an adhesive which has not fully solidified yet, and thereby unified into a thin metal wire bundle 30. As the adhesive, an adhesive having a viscosity lower than that of resin is used such that the adhesive does not have a high space factor in thin metal wire bundle 30.

Preferably, an adhesive which solidifies in two steps is used. When the adhesive which solidifies in two steps is used, thin metal wire bundle 30 is unified by solidification in the first step, then thin metal wire bundle 30 is compression-molded by press working as described later, and thereafter solidification in the second step is performed. Thereby, it becomes possible to maintain a state in which conductive material 11 has a high space factor.

Press working is performed as shown in FIG. 4 by placing thin metal wire bundle 30 on lower mold 3, moving upper mold 4 downward, and sandwiching thin metal wire bundle 30 between lower molding surface 3a and upper molding surface 4a.

FIG. 7 is a partial perspective view showing an outer appearance of the thin metal wire electromagnetic shield formed by being compression-molded by press working in the present embodiment. As shown in FIG. 7, a thin metal wire electromagnetic shield 30a compression-molded by press working has an outer shape which follows the shapes of lower molding surface 3a and upper molding surface 4a. By compression-molding thin metal wire bundle 30 by press working, thin metal wire electromagnetic shield 30a having a desired shape is fabricated.

Since thin metal wire electromagnetic shield 30a is compression-molded, gaps between thin metal wires 10 are reduced. As a result, the space factor of conductive material 11 in thin metal wire electromagnetic shield 30a is higher than the space factor of conductive material 11 in thin metal wire bundle 30. When the adhesive fully solidifies in this state, the state in which conductive material 11 has a high space factor is maintained.

By forming thin metal wire electromagnetic shield 30a as described above, the space factor of conductive material 11 can be increased and the magnetic flux shielding capability of thin metal wire electromagnetic shield 30a can be improved. There are some cases where the thin metal wire bundle cannot be unified by twisting as in Embodiment 1, depending on the degrees of thickness and hardness of thin metal wire 10. In that case, it is effective to unify the thin metal wire bundle with an adhesive as in the present embodiment.

Hereinafter, a shell-type transformer in accordance with Embodiment 3 including the thin metal wire electromagnetic shield described above will be described. Although a transformer will be described as a stationary induction apparatus in the following description of the embodiments, the stationary induction apparatus is not limited to a transformer, and may be, for example, a reactor or the like.

### Embodiment 3

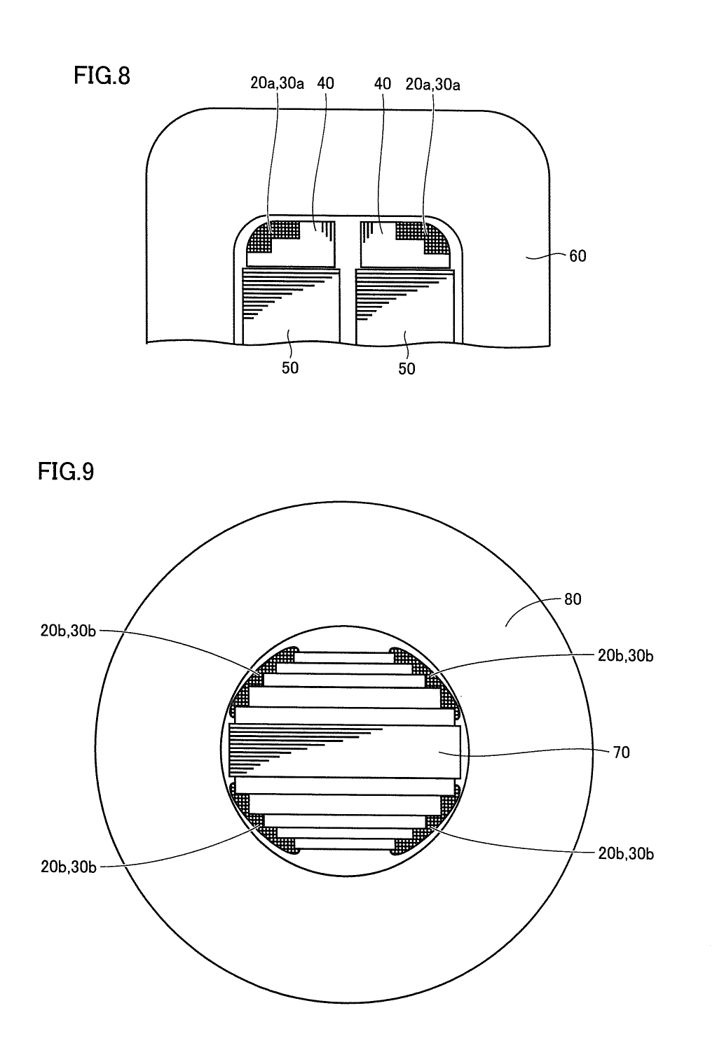

FIG. 8 is a partial cross sectional view showing a configuration of a shell-type transformer in accordance with Embodiment 3 of the present invention. As shown in FIG. 8, the shell-type transformer includes an iron core 50 having a plurality of laminated magnetic steel sheets, a winding 60 wound around iron core 50, and thin metal wire electromagnetic shield 20a located between iron core 50 and winding 60.

In the present embodiment, an electromagnetic shield 40 is formed between an inner peripheral surface of winding 60 and the magnetic steel sheet of iron core 50 facing the inner peripheral surface, by laminating electromagnetic steel sheets in a so-called upright state. Thereby, an eddy current loss in iron core 50 can be reduced.

By actively passing a magnetic flux through the electromagnetic steel sheets constituting electromagnetic shield 40, the magnetic flux can be suppressed from flowing into a portion other than that. It is noted that the reason why the electromagnetic steel sheets are laminated in a so-called upright state is to suppress loss, considering the flow of the magnetic flux. Specifically, by causing the magnetic flux to flow in from a surface in which thin electromagnetic steel sheets are laminated, a cross section through which an eddy current flows can be reduced. Thereby, loss can be suppressed.

However, in a curved portion of the inner peripheral surface of winding 60, the distance between the surface of iron core 50 and the inner peripheral surface of winding 60 decreases gradually, and thus it is not possible to arrange an electromagnetic steel sheet having the same width as that in other portions.

Thus, in the transformer in accordance with the present embodiment, thin metal wire electromagnetic shield 20a is arranged to fit the curved portion of winding 60. Since thin metal wire electromagnetic shield 20a can be formed into a desired shape by press working, it can be arranged at a narrow gap having a complicated shape.

By arranging thin metal wire electromagnetic shield 20a at the curved portion of the inner peripheral surface of winding 60, a magnetic flux can be effectively blocked from entering iron core 50. It is noted that, although thin metal wire electromagnetic shield 20a in accordance with Embodiment 1 is used in the present embodiment, thin metal wire electromagnetic shield 30a in accordance with Embodiment 2 may also be used.

Further, an electromagnetic shield may be entirely composed of thin metal wire electromagnetic shield 20a or thin metal wire electromagnetic shield 30a, without using electromagnetic shield 40.

Hereinafter, a core-type transformer in accordance with Embodiment 4 including the thin metal wire electromagnetic shield described above will be described. Since the core-type transformer in accordance with the present embodiment is different from the shell-type transformer in accordance with Embodiment 3 only in not having electromagnetic shield 40, a description of other features will not be repeated.

### Embodiment 4

FIG. 9 is a partial cross sectional view showing a configuration of a core-type transformer in accordance with Embodiment 4 of the present invention. As shown in FIG. 9, the core-type transformer includes an iron core 70 having a plurality of laminated magnetic steel sheets, a winding 80 wound around iron core 70, and a thin metal wire electromagnetic shield 20b located between iron core 70 and winding 80.

In the present embodiment, the magnetic steel sheets constituting iron core 70 have widths which decrease in a stepwise manner with approaching an inner peripheral surface of winding 80. In the core-type transformer in accordance with the present embodiment, thin metal wire electromagnetic shield 20b is arranged to fit a side surface of iron core 70 and a curved portion of winding 80. Thin metal wire electromagnetic shield 20b is different from thin metal wire electromagnetic shield 20a only in shape.

By arranging thin metal wire electromagnetic shield 20b at the side surface of iron core 70 and the curved portion of the inner peripheral surface of winding 80, a magnetic flux can be effectively blocked from entering iron core 70. It is noted that, although thin metal wire electromagnetic shield 20b in accordance with Embodiment 1 is used in the present embodiment, a thin metal wire electromagnetic shield 30h in accordance with Embodiment 2 may also be used. Thin metal wire electromagnetic shield 30b is different from thin metal wire electromagnetic shield 30a only in shape.

It is noted that the embodiments disclosed herein are illustrative in every respect, and offer no basis for restrictive interpretation. Therefore, the technical scope of the present invention should not be interpreted by the above embodiments only, and is defined based on the description in the scope of the claims. Further, any modifications within the scope and meaning equivalent to the scope of the claims are included.

### REFERENCE SIGNS LIST

1: press working machine; 2: base; 3: lower mold; 3a: lower molding, surface; 4: upper mold; 4a: upper molding surface; 10: thin metal wire; 11: conductive material; 12: insulating material; 20, 30: thin metal wire bundle; 20a, 20b, 30a, 30b: thin metal wire electromagnetic shield; 40: electromagnetic shield; 50, 70: iron core; 60, 80: winding.

1. A method for manufacturing a thin metal wire electromagnetic shield, comprising:
preparing a thin metal wire bundle unified by bundling a plurality of thin metal wires each having a surface coated with an insulating material; and
compression-molding said thin metal wire bundle by press working.

2. The method for manufacturing the thin metal wire electromagnetic shield according to claim 1, wherein said step of preparing said thin metal wire bundle includes the step of unifying said thin metal wire bundle by twisting said plurality of thin metal wires in a bundled state.

3. The method for manufacturing the thin metal wire electromagnetic shield according to claim 1, wherein said step of preparing said thin metal wire bundle includes the step of unifying said thin metal wire bundle by bonding said plurality of thin metal wires together with an adhesive.

4. A thin metal wire electromagnetic shield, comprising:
a thin metal wire bundle compression-molded by press working in a unified state in which a plurality of thin metal wires each having a surface coated with an insulating material are bundled.

5. The thin metal wire electromagnetic shield according to claim 4, wherein said thin metal wire bundle is unified by twisting said plurality of thin metal wires in a bundled state.

6. The thin metal wire electromagnetic shield according to claim 4, wherein said thin metal wire bundle is unified by bonding said plurality of thin metal wires together with an adhesive.

7. A stationary induction apparatus, comprising:
an iron core;
a winding wound around said iron core; and
a thin metal wire electromagnetic shield located between said iron core and said winding,
wherein said thin metal wire electromagnetic shield includes a thin metal wire bundle compression-molded by press working in a unified state in which a plurality of thin metal wires each having a surface coated with an insulating material are bundled.

8. The stationary induction apparatus according to claim 7, wherein said thin metal wire bundle is unified by twisting said plurality of thin metal wires in a bundled state.

9. The stationary induction apparatus according to claim 7, wherein said thin metal wire bundle is unified by bonding said plurality of thin metal wires together with an adhesive.
